(19) United States
(12) Patent Application Publication
(10) Pub. No.: US 2012/0308810 A1
(43) Pub. Date: Dec. 6, 2012

(54) COATED ARTICLE AND METHOD FOR MAKING THE SAME

(75) Inventors: DA-HUA CAO, Shenzhen City (CN); XU LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/178,669

(22) Filed: Jul. 8, 2011

(30) Foreign Application Priority Data
Jun. 2, 2011 (CN) 201110147463.7

(51) Int. Cl. C23C 14/06; B32B 9/00; C23C 14/35; B32B 15/04

(52) U.S. Cl. 428/336; 428/688; 428/457; 204/192.11

(57) ABSTRACT

A coated article includes a substrate and a DLC layer formed on the substrate. More than 80% of carbon-carbon bonds in the DLC layer are sp³ carbon-carbon bonds. The DLC layer is dense and has a good cosmetic effect, excellent abrasion resistance and an excellent corrosion resistance.

### BACKGROUND

1. Technical Field

The present disclosure relates to a coated article and a method for making the coated article.

2. Description of Related Art

A diamond-like Carbon (DLC) layer is an amorphous carbon layer. The carbon atoms generally exist in their diamond phase form (carbon-carbon bonds in the form of sp³) and in their graphite phase form (carbon-carbon bonds in the form of sp²) in the DLC layer. When the amount of the diamond phase is greater than the graphite phase, the DLC layer has excellent abrasion resistance and excellent corrosion resistance. However, DLC layers which have been fabricated by multi-arc ion plating or by chemical vapor deposition (CVD) process are often not smooth on the surface and not inherently dense. Additionally, the CVD process requires a deposition temperature between 600° C. and 1000° C., which tends to cause damage to the substrate.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a coated article;

FIG. 2 is a schematic view of a vacuum sputtering device for processing the coated article in FIG. 1.

### DETAILED DESCRIPTION

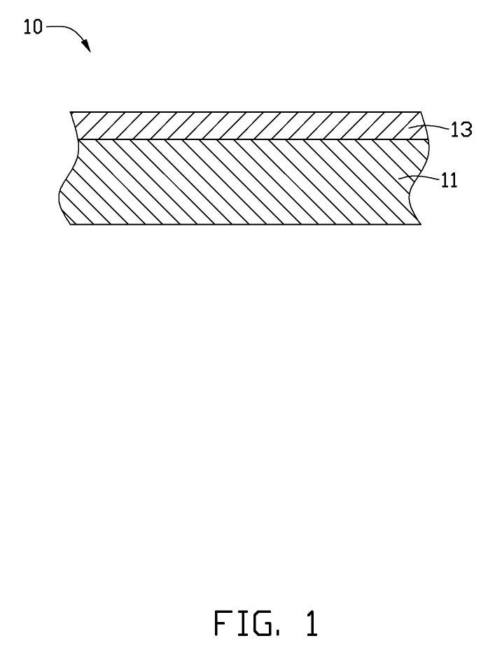

FIG. 1 shows a coated article 10 according to an exemplary embodiment. The coated article 10 includes a substrate 11 and a DLC layer 13 formed on a surface of the substrate 11. The coated article 10 may be used as housing of a computer, a communication device, or a consumer electronics product.

The substrate 11 may be made of stainless steel, aluminum alloy or titanium alloy, but is not limited to those materials.

The DLC layer 13 has a thickness of about 2.2 μm to about 2.8 μm. A vacuum sputtering process may be used to form the DLC layer 13. More than 80% of carbon-carbon bonds in the DLC layer 13 are sp³ carbon-carbon bonds. In the DLC layer 13, there are still carbon-hydrogen bonds. The DLC layer 13 is dense and has a good cosmetic appearance, excellent abrasion resistance and an excellent corrosion resistance.

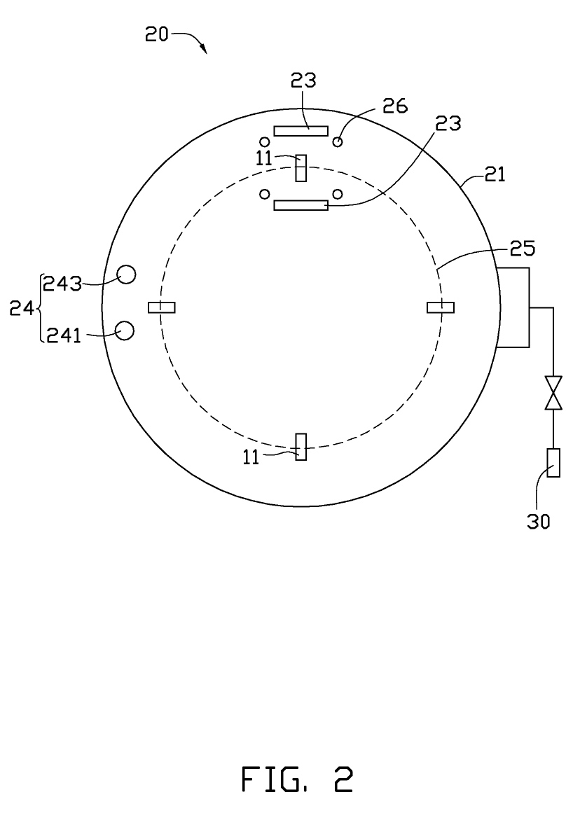

FIG. 2 shows a vacuum sputtering device 20 according to an exemplary embodiment. The vacuum sputtering device 20 includes a vacuum chamber 21 and a vacuum pump 30 connected to the vacuum chamber 21. The vacuum pump 30 is used for evacuating air from the vacuum chamber 21. The vacuum chamber 21 has a pair of graphite targets 23, ion sources 24, gas source channels 26 and a rotary rack (not shown) positioned therein. The rotary rack holding the substrate 11 revolves along a circular path 25, and the substrate 11 is also revolved about its own axis while being carried by the rotary rack. The ion source 24 includes a medium-energy source 241 (ion energy in a range from 10×10³ electron volts (eV) to 30×10³ eV) and a low-energy ion source 243 (ion energy in a range from 100 eV to 750 eV). The reaction gas is ionized in the ion source 24 and fed into the vacuum chamber 21. The sputtering gas is fed into the vacuum chamber 21 through the gas source channels 26.

An exemplary method for making the coated article 10 may include at least the following steps:

The substrate 11 is pretreated. The pre-treating process may include degreasing, wax removal, rinsing by deionized water and drying steps.

The DLC layer 13 is formed on the pretreated substrate 11 by the ion beam assisted magnetron sputtering process. The ion beam assisted magnetron sputtering of the DLC layer 13 is implemented in the vacuum chamber 21. The substrate 11 is positioned in the rotary rack. The vacuum chamber 21 is evacuated of air to about 6.0×10⁻³ Pa and is heated to a temperature of about 150° C. to about 200° C. Argon gas (abbreviated as Ar, having a purity of about 99.999%) is used as sputtering gas and is fed into the vacuum chamber 21 at a flow rate of about 120 sccm to about 150 sccm. The graphite targets 23 are supplied with electrical power of about 15 kw to about 18 kw. A negative bias voltage is applied to the substrate 11 in the range from about −150 volts (V) to about −200 V. Methane (CH₄) is fed into the ion source 24 at a flow rate of about 50 sccm to about 60 sccm. The medium-energy source 241 and the low-energy ion source 243 are powered on and an electrical current of about 60 mA to about 80 mA is applied to the low-energy ion beam, the current applied to the medium-energy ion beam is about 10 mA to about 20 mA.

During the deposition process, Ar in the vacuum chamber 21 produces a glowing discharge and is ionized to Ar plasma under the electromagnetic fields. Ar plasma strikes the graphite target 23 and some carbon atoms in the graphite target 23 are taken out by the Ar plasma and deposit on the substrates 11. Furthermore, some carbon ions from the ion source 24 strike the substrate 11 and a portion of those carbon ions deposits on the substrate 11. More than 80% of carbon-carbon bonds in the DLC layer 13 are sp³ carbon-carbon bonds. A small amount of hydrogen ions from the ion source 24 are also deposited on the substrate 11.

### EXAMPLES

Experimental examples of the present disclosure are described as followings.

### Example 1

The vacuum sputtering device 20 in example 1 was a medium frequency magnetron sputtering device.

The substrate 11 was made of stainless steel.

Sputterring to form the DLC layer 13 took place, wherein the vacuum chamber 21 was heated to a temperature of about 180° C. to about 200° C. Ar was fed into the vacuum chamber 21 at a flow rate of about 140 sccm. The graphite targets 23 are supplied with a power of about 15 kw, and a negative bias voltage of about −150 V was applied to the substrate 11. CH₄ was fed into the ion source 24 at a flow rate of about 50 sccm. A current of about 60 mA was applied to the low-energy ion beam and a current of about 10 mA was applied to the medium-energy ion beam. The depositing of the DLC layer 13 took about 480 min.

### Example 2

The vacuum sputtering device 20 in example 2 was the same in example 1.

The substrate 11 was made of stainless steel.

Sputtering to form the DLC layer 13 took place, wherein the vacuum chamber 21 was heated to a temperature of about 180° C. to about 200° C. Ar was fed into the vacuum chamber 21 at a flow rate of about 150 sccm. The graphite targets 23 are supplied with a power of about 17 kw, and a negative bias voltage of about −150 V was applied to the substrate 11. CH₄ was fed into the ion source 24 at a flow rate of about 60 sccm. A current of about 80 mA was applied to the low-energy ion beam and a current of about 15 mA was applied to the medium-energy ion beam. The depositing of the DLC layer 13 took about 420 min.

### Results of the Above Examples

The coated articles 10 made in example 1 and 2 were done abrasion test, the Vickers hardness test, the pencil hardness test and the salt spray test.

Abrasion test: the test device used was a vibration wear test device (model No. Trough vibrator R180/530 TE-30) manufactured by Rosler Co., Ltd., located in Germany The coated articles 10 described in example 1 and 2 both showed no peeling of the DLC layer 13 after being abraded for 4 hours.

Vickers hardness test: the test device used was a Vickers hardness tester. Vickers hardness of the DLC layers described in examples 1 and 2 were 469 HV and 500 HV, respectively.

Pencil hardness test: the test device used was a pencil hardness tester, the load force was 5 Newtons. Pencil hardness of the DLC layer described in examples 1 and 2 were both equal to and greater than 6H.

Salt spray test: the test device used was a salt spray tester (model No. TMJ9701), the concentration of the sodium chloride in solution was 5%. The coated articles 10 described in example 1 and 2 both showed no corrosion after being tested for 144 hours.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
a DLC layer formed on the substrate, wherein more than 80% of carbon-carbon bonds in the DLC layer are sp³ carbon-carbon bonds.

2. The coated article as claimed in claim 1, wherein the DLC layer further includes carbon-hydrogen bonds.

3. The coated article as claimed in claim 1, wherein the substrate is made of stainless steel, aluminum alloy or titanium alloy.

4. The coated article as claimed in claim 1, wherein the DLC layer is made by ion beam assisted magnetron sputtering process.

5. The coated article as claimed in claim 1, wherein the DLC layer has a thickness of about 2.2 μm to about 2.8 μm.

6. A method for making a coated article, comprising:
providing a substrate; and
forming a DLC layer on the substrate by ion beam assisted magnetron sputtering process, the forming process uses graphite targets and uses methane gas as reaction gas of the ion source; more than 80% of carbon-carbon bonds in the DLC layer are sp³ carbon-carbon bonds.

7. The method as claimed in claim 6, wherein magnetron sputtering the DLC layer uses argon gas as sputtering gas and argon gas has a flow rate of about 120 sccm to 150 sccm; magnetron sputtering the DLC layer is at a temperature of about 150° C. to about 200° C., the graphite targets are supplied with a power of about 15 kw to about 18 kw, a negative bias voltage of about −150V to about −200V is applied to the substrate; methane gas has a flow rate of about 50 sccm to 60 sccm, the ion source includes a medium-energy ion source and a low-energy ion source, a current of about 60 mA to about 80 mA is applied to the low-energy ion beam, a current of about 10 mA to about 20 mA is applied to the medium-energy ion beam, vacuum sputtering the DLC layer takes about 420 min to about 480 min.

8. The method as claimed in claim 6, wherein the DLC layer further includes carbon-hydrogen bonds.

9. The method as claimed in claim 6, wherein the substrate is made of stainless steel, aluminum alloy or titanium alloy.

10. The method as claimed in claim 6, wherein the DLC layer has a thickness of about 2.2 μm to about 2.8 μm.
